(19) United States
(12) Patent Application Publication
(10) Pub. No.: US 2024/0421822 A1
(43) Pub. Date: Dec. 19, 2024

(54) LEVEL SHIFT CIRCUIT

(71) Applicant: ROHM CO., LTD., Kyoto-shi (JP)

(72) Inventor: Seiji TAKENAKA, Kyoto-shi (JP)

(21) Appl. No.: 18/820,689

(22) Filed: Aug. 30, 2024

Related U.S. Application Data
(63) Continuation of application No. PCT/JP2023/004538, filed on Feb. 10, 2023.

(30) Foreign Application Priority Data
Mar. 1, 2022 (JP) 2022-030820

(51) Int. Cl. H03K 19/0185; H03K 3/356

(52) U.S. Cl. CPC H03K 19/018528; H03K 3/35613

(57) ABSTRACT

A level shift circuit includes: a level information output circuit configured to output level information on an input signal; a latch circuit configured to operate between a first voltage and a reference voltage lower than the first voltage to latch the output of the level information output circuit; and a voltage controller configured to raise the first voltage to a first set value after completion of latching by the latch circuit, then, when the first voltage reaches the first set value, to raise the reference voltage to a second set value, and then, after raising the reference voltage to the second set value, to raise the first voltage to a third set value.

### CROSS-REFERENCE TO RELATED APPLICATIONS

This application is a continuation under 35 U.S.C. § 120 of. PCT/JP2023/004538 filed on Feb. 20, 2023, which is incorporated herein by reference, and which claimed priority to Japanese Patent Application No. 2022-030820 filed in Japan on Mar. 1, 2022. The present application likewise claims priority under 35 U.S.C. § 119 to Japanese Patent Application No. 2022-030820 filed in Japan on Mar. 1, 2022, the entire content of which is also incorporated herein by reference.

### BACKGROUND OF THE INVENTION

### 1. Technical Field

The disclosure herein relates to a level shift circuit.

### 2. Description of Related Art

Conventionally, level shift circuits for transmitting signals between different voltage domains are used in various applications.

An example of known technology related to what has just been mentioned is seen in JP-A-2012-70333.

### BRIEF DESCRIPTION OF THE DRAWINGS

FIG. 1 is a diagram showing a comparative example of a level shift circuit.

FIG. 2 is a diagram showing a level shift circuit according to an embodiment.

FIG. 3 is a diagram showing how relevant voltages change with time.

FIG. 4 is a diagram showing how relevant voltages change with time.

FIG. 5 is a diagram showing one example of the level shift circuit, an inverter, and a buffer.

FIG. 6 is a diagram showing a modified example of the level shift circuit.

### DESCRIPTION OF EMBODIMENTS

In the present description, a MOSFET (metal-oxide-semiconductor field-effect transistor) denotes a field-effect transistor in which the gate is structured to have at least three layers: a layer of an electrical conductor or of a semiconductor such as polysilicon with a low resistance value, an insulation layer, and a P-type, N-type or intrinsic semiconductor layer. That is, the MOSFET may have any gate structure other than a three-layer structure composed of a metal, an oxide, and a semiconductor.

### <Level Shift Circuit (Comparative Example)>

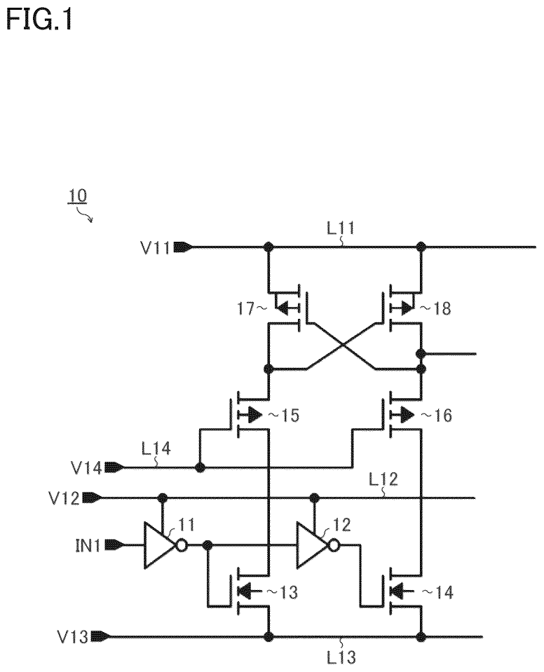

FIG. 1 is a diagram showing a comparative example (that is, a common configuration to be compared with the embodiments which will be described later) of a level shift circuit. The level shift circuit 10 of this comparative example includes inverters 11 and 12, transistors 13 and 14 (for example, NMOSFETs [n-channel type MOSFETs]), transistors 15 to 19 (PMOSFETs [p-channel type MOSFETs]), a first voltage line L11, a second voltage line L12, a third voltage line L13, and a fourth voltage line L14.

The first voltage line L11 is fed with a first voltage V11 (for example, 20 V). The second voltage line L12 is fed with a second voltage V12 (for example, 5 V). The third voltage line L13 is fed with a third voltage V13 (for example, 0 V). The fourth voltage line L14 is fed with a fourth voltage V14 (for example, 14 V).

The inverter 11 operates by being supplied with the second voltage V12; it logically inverts the input signal IN1 and outputs the result. The inverter 12 logically inverts the output signal of the inverter 11 and outputs the result.

The gate of the transistor 13 is connected to the output terminal of the inverter 11. The gate of the transistor 14 is connected to the output terminal of the inverter 12. The sources of the transistors 13 and 14 are both connected to the third voltage line L13.

The drain of the transistor 15 is connected to the drain of the transistor 13. The drain of the transistor 16 is connected to the drain of the transistor 14. The gates of the transistors 15 and 16 are both connected to the fourth voltage line L14.

The drain of the transistor 17 and the gate of the transistor 18 are both connected to the source of the transistor 15. The drain of the transistor 18 and the gate of the transistor 17 are both connected to the drain of the transistor 16. The sources of the transistors 17 and 18 are both connected to the first voltage line L11.

The gate of the transistor 19 is connected to the drain of the transistor 18 (corresponding to the output terminal for the output signal OUT1).

In the level shift circuit 10 of this comparative example, when the input signal IN1 is at high level (=V12), the output signal OUT1 is at low level (=V14+Vgs16, where Vgs16 is the gate-source voltage of the transistor 16). By contrast, when the input signal IN1 is at low level (=V13), the output signal OUT1 is at high level (=V11).

That is, the level shift circuit 10 of this comparative example shifts the level of the input signal IN1, which is in a low voltage domain (for example, 5V/0V), to generate an output signal OUT1 in a high voltage domain (for example, 20V/15V).

However, in the level shift circuit 10 of this comparative example, a high voltage (=V11-V13) can be fed between the drain and the source of those transistors 13 to 16. Thus, it is necessary to use high-withstand-voltage elements as transistors 13 to 16, and this leads to an increase in the circuit area.

In view of the foregoing, the following description presents a novel embodiment that can reduce the withstand voltage of the internal elements of the level shift circuit.

### <Level Shift Circuit (Comparative Example)>

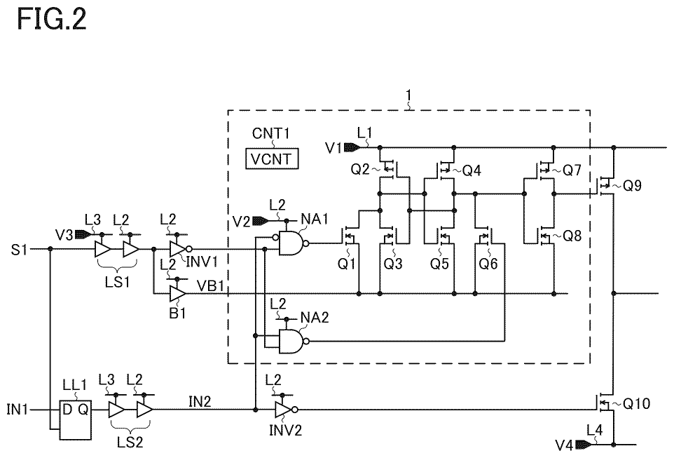

FIG. 2 is a diagram showing a level shift circuit according to an embodiment. The level shift circuit 1 of this embodiment includes NAND gates NA1 and NA2, transistors Q1, Q3, Q5, Q6, and Q8 (for example, NMOSFETs), transistors Q2, Q4, Q6, and Q7 (for examples, PMOSFETs), a first voltage line L1, a second voltage line L2, and a voltage controller CNT1.

Circuits peripheral to the level shift circuit 1 include a level latch circuit LL1, level shift circuits LS1 and LS2, inverters INV1 and INV2, a buffer B1, a transistor Q9 (for example, a PMOSFET), a transistor Q10 (for example, an NMOSFET), a third voltage line L3, and a fourth voltage line L4.

The first voltage line L1 is fed with a first voltage V1. The second voltage line L2 is fed with a second voltage V2. The third voltage line L3 is fed with a third voltage V3. The fourth voltage line L4 is fed with a fourth voltage V4. The voltage controller CNT1 controls the first and second voltages V1 and V2. In a configuration where a plurality of level shift circuits 1 are provided, the voltage controller CNT1 can be shared among a plurality of level shift circuits 1.

The first voltage V1 is fed to the sources of the transistors Q2, Q4, Q7, and Q9. The second voltage V2 is fed to the level shift circuit LS1, the inverter INV1, the buffer B1, the NAND gates NA1 and NA2, and the inverter INV2. The third voltage V3 is fed to the level shift circuits LS1 and LS2. The fourth voltage V4 is fed to the source of the transistor Q10. The fourth voltage V4 is used also as a reference voltage for the level shift circuit LS1, the inverter INV1, the buffer B1, the NAND gates NA1 and NA2, and the inverter INV2.

A latch control signal S1 is fed to the level shift circuit LS1 so that its level is shifted by the level shift circuit LS1. The level shift circuit LS1 is constituted solely by low-withstand-voltage elements. The output of the level shift circuit LS1 is inverted by the inverter INV1 and then fed to the second input terminal of the NAND gate NA1 and to the first input terminal of the NAND gate NA2. The output of the level shift circuit LS1 is fed via a buffer B1 to the sources of the transistors Q1, Q3, Q5, Q6, and Q8.

In the output of each of the inverter INV1 and the buffer B1, only the timing of the transition from high level to low level is delayed.

In a configuration where a plurality of level shift circuits 1 are provided, the level shift circuit LS1, the inverter INV1, and the buffer B1 can be shared among the plurality of level shift circuits 1.

The first input signal IN1 is fed to a data input terminal (D terminal) of the level latch circuit LL1. The level latch circuit LL1 is also fed with the latch control signal S1. When the latch control signal S1 is at low level, the level latch circuit LL1 outputs the first input signal IN1 fed to the data input terminal (D terminal) as it is from the output terminal (Q terminal). By contrast, when the latch control signal S1 turns from low level to high level, the level latch circuit LL1 latches the level of the first input signal IN1 fed to the data input terminal (D terminal).

The output of the level latch circuit LL1 is fed to the level shift circuit LS2 so that its level is shifted by the level shift circuit LS2. The level shift circuit LS2 is constituted solely by low-withstand-voltage elements. The output of the level shift circuit LS2 is inverted and then fed to the first input terminal of the NAND gate NA1. The output of the level shift circuit LS2 is also fed to the second input terminal of the NAND gate NA2. The output of the level shift circuit LS2 is an input signal (second input signal IN2) to the level shift circuit 1. The output of the level shift circuit LS2 is in addition inverted by the inverter INV2 and then fed to the gate of transistor Q10.

The output of the NAND gate NA1 is fed to the gate of the transistor Q1. The output of the NAND gate NA2 is fed to the gate of the transistor Q6.

The transistors Q2 to Q5 constitute a differential latch circuit. The latch circuit includes a first inverter constituted by the transistors Q2 and Q3 and a second inverter constituted by the transistors Q4 and Q5. The output terminal of the first inverter (the connection node between the drains of the transistors Q2 and Q3) is connected to the input terminal of the second inverter (the connection node between the gates of the transistors Q4 and Q5). The output terminal of the second inverter (the connection node between the drains of the transistors Q4 and Q5) is connected to the input terminal of the first inverter (the connection node between the gates of the transistors Q2 and Q3).

The drain of the transistor Q1 is connected to the output terminal of the first inverter and the input terminal of the second inverter. The drain of the transistor Q6 is connected to the output terminal of the first inverter and the input terminal of the second inverter. The output of the second inverter, that is, the output of the latch circuit described above, is inverted by the third inverter constituted by the transistors Q7 and Q8 and then fed to the gate of the transistor Q9. The drain of the transistor Q9 is connected to the drain of the transistor Q10.

In the level shift circuit 1, the NAND gates NA1 and NA2 and the transistors Q1 and Q6 function as a level information output circuit configured to output level information on the second input signal IN2.

In the level shift circuit 1, the transistors Q2 to Q5 function as a latch circuit configured to operate between the first voltage V1 and a reference voltage (the output voltage VB1 of the buffer B1) lower than the first voltage V1 to latch the output of the level information output circuit described above.

The voltage controller CNT1 is configured to raise the first voltage V1 to a first set value after completion of the latching by the latch circuit described above, then, when the first voltage V1 reaches the first set value, to raise the reference voltage VB1 to a second set value, and then, after raising the reference voltage VB1 to the second set value, to raise the first voltage V1 to a third set value.

Through control by the voltage controller CNT1 as described above, after completion of the latching by the latch circuit described above, that is, after determination of the logic by the level shift circuit 1, the first voltage V1 can be raised to the third set value while the latch circuit described above is maintaining its operation state and keeping the difference between the first voltage V1 and the reference voltage VB1 low. Thus, it is possible to reduce the withstand voltage of the internal elements of the level shift circuit 1.

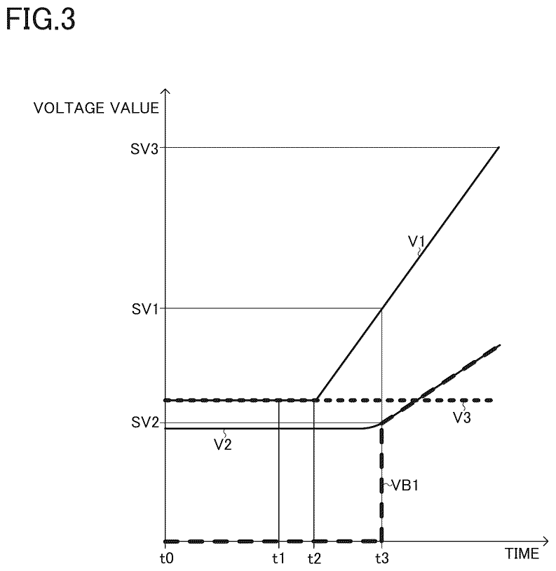

Now, the operation of the level shift circuit 1 will be described in detail with reference to FIG. 3. FIG. 3 is a diagram showing how the relevant voltages change with time. In FIG. 3, the horizontal axis represents time and the vertical axis represents voltage value.

At time to, the latch control signal S1 is at low level. At time t0, the voltage controller CNT1 sets the first and third voltages V1 and V3 to an equal value and sets the second voltage V2 to the middle value between the first voltage V1 and the reference voltage VB1.

Before time t1, the first input signal IN1 with its level determined is fed to the data input terminal (D terminal) of the level latch circuit LL1.

Here, a description will be given of a case where the first input signal IN1 is at low level. In this case, the second input signal IN2 output from the output terminal (Q terminal) of the level latch circuit LL1 is at low level. Between the output terminal (Q terminal) of the level latch circuit LL1 and the gate of the transistor Q10, a level shift circuit LS2 and an inverter INV2 are arranged. Thus, the signal fed to the gate of the transistor Q10 is at high level, and the transistor Q10 is on. Accordingly, the drain voltage of the transistor Q10 is at low level.

The second input signal IN2 fed from the level shift circuit LS2 to the first input terminal of the NAND gate NA2 is at low level. Thus, the signal fed from the NAND gate NA2 to the gate of the transistor Q6 is at high level. Accordingly, the transistor Q6 is on. The current capacity of the transistor Q6 is set higher than that of the transistor Q4; thus, the signal fed to the gates of the transistors Q7 and Q8 is at low level. As described above, the transistors Q7 and Q8 constitute the third inverter; thus, the signal fed to the gate of transistor Q9 is at high level. Accordingly, the transistor Q9 is off. Since the drain of the transistor Q9 is connected to the source of the transistor Q10, the source voltage of transistor Q10 remains at low level.

The second input signal IN2 fed out from the level shift circuit LS2 is inverted and then fed to the first input terminal of the NAND gate NA1. The signal fed from the inverter INV1 to the second input terminal of the NAND gate NA1 is also at high level. Thus, the signal fed from the NAND gate NA1 to the gate of the transistor Q1 is at low level. Accordingly, the transistor Q1 is off, and the drain of the transistor Q1 is open. As described above, the transistor Q6 is on, and thus the signal fed to the gates of the transistors Q2 and Q3 is at low level. As described above, the transistors Q2 and Q3 constitute the first inverter; thus, the output of the first inverter is at high level. As described above, the transistors Q4 and Q5 constitute the second inverter. The second inverter inverts the output of the first inverter and feeds the result to the input terminal of the first inverter.

Next, a description will be given of a case where the first input signal IN1 is at high level. In this case, the second input signal IN2 output from the output terminal (Q terminal) of the level latch circuit LL1 is at high level. Between the output terminal (Q terminal) of the level latch circuit LL1 and the gate of the transistor Q10, the level shift circuit LS2 and the inverter INV2 are arranged. Thus, the signal fed to the gate of the transistor Q10 is at low level, and the transistor Q10 is off. Accordingly, the drain of the transistor Q10 is open.

The second input signal IN2 fed from the level shift circuit LS2 to the first input terminal of the NAND gate NA2 is at high level. Also, the signal fed from the inverter INV1 to the second input terminal of the NAND gate NA2 is at high level. Thus, the signal fed from the NAND gate NA2 to the gate of the transistor Q6 is at low level. Accordingly, the transistor Q6 is off.

The second input signal IN2 fed out from the level shift circuit LS2 is inverted and fed to the first input terminal of the NAND gate NA1; thus, the signal fed from the NAND gate NA1 to the gate of the transistor Q1 is at high level. Accordingly, the transistor Q1 is on. Since the current capacity of the transistor Q1 is set higher than that of the transistor Q2, the signal fed to the gates of transistors Q4 and Q5 is at low level. As described above, the transistors Q4 and Q5 constitute the second inverter; thus, the output of the second inverter is at high level. Thus, the signal fed to the input terminal of the first inverter constituted by the transistors Q2 and Q3 and to the input terminal of the third inverter constituted by the transistors Q7 and Q8 is at high level. The signal fed from the output terminal of the third inverter to the gate of the transistor Q9 is at low level. Accordingly, the transistor Q9 is on. Since the drain of the transistor Q9 is connected to the source of the transistor Q10, the source voltage of the transistor Q10 is at high level.

After time t1, starting at time t2, the voltage controller CNT1 raises the first voltage V1. After time t2, when at time t3 the first voltage V1 reaches the first set value SV1, the level of the latch control signal S1 is switched from low level to high level.

The first set value SV1 is a value that permits the latch circuit described above to operate between the first voltage V1 and the reference voltage VB1 even if the reference voltage VB1 and the second voltage V2 have an equal value. At time t3, the second voltage V2 has the second set value SV2. The second set value SV2 is a value that permits the NAND gates NA1 and NA2 and the inverter INV2 to operate.

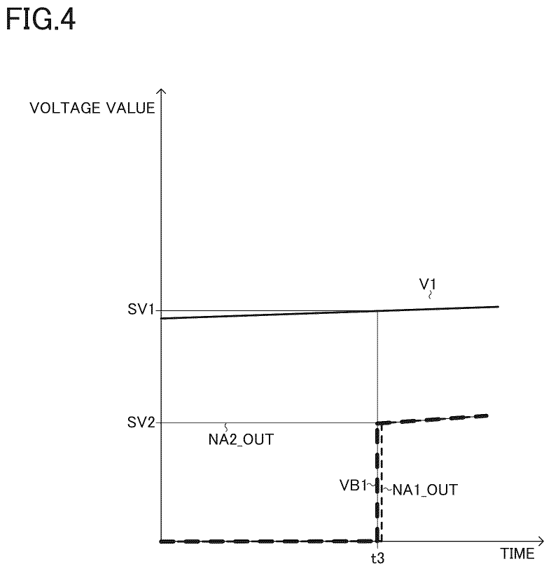

FIG. 4 is a diagram showing how the relevant voltages change with time before and after time t3, that is, before and after completion of the latching by the latch circuit. In FIG. 4, the horizontal axis represents time, and the vertical axis represents voltage value. FIG. 4 shows an example where the second input signal IN2 is at low level.

Before time t3, the output NA1_OUT of the NAND gate NA1 is at low level, and the output NA2_OUT of the NAND gate NA2 is at high level. At time t3, the level of the latch control signal S1 switches from low level to high level and, with a slight delay from t3 produced in the inverter INV1, the output NA1_OUT of the NAND gate NA1 switches from low level to high level (relative to the fourth voltage V4). However, after time t3, the reference voltage VB1 of the latch circuit rises to the second setting value SV2. Thus, after time t3, the high level (relative to the fourth voltage) of the output NA1_OUT of the NAND gate NA1 is the low level in the latch circuit. Accordingly, after the output NA1_OUT of the NAND gate NA1 switches from low level to high level (relative to the fourth voltage V4), the drains of the transistors Q1 and Q6 are open. That is, after completion of latching, the latch circuit is not reset.

Starting at time t3, the voltage controller CNT1 raises the first voltage V1 to the third set value SV3. In this way, it is possible to increase the amount of level shift in the level shift circuit 1 to a predetermined value.

Here, it is preferable that the voltage controller CNT1 be configured to raise the reference voltage VB1 from the second set value SV2 during the period in which the first voltage V1 is raised from the first set value SV1 to the third set value SV3. This allows the level shift circuit 1 to increase the first voltage V1 to the third set value SV3 while keeping the difference between the first voltage V1 and the reference voltage VB1 even lower.

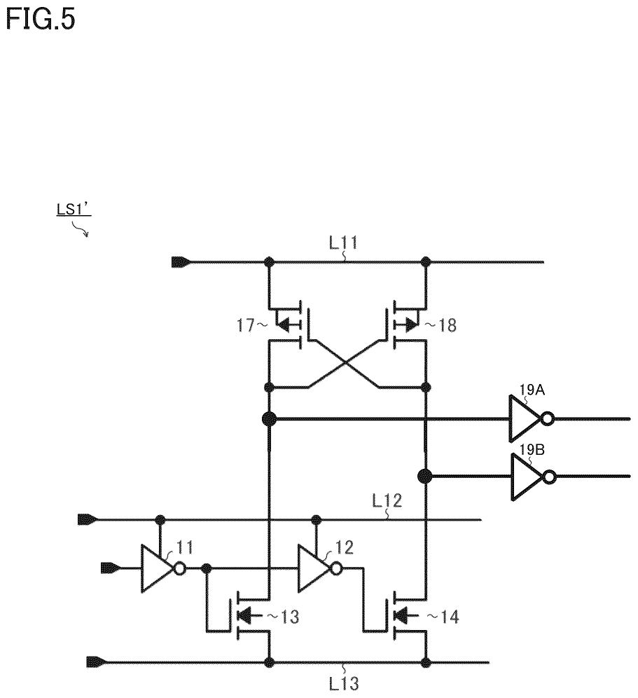

FIG. 5 is a diagram showing one example of the level shift circuit LS1, the inverter INV1, and the buffer B1.

The level shift circuit LS1′ shown in FIG. 5 results from modifying the level shift circuit 10 shown in FIG. 1 by removing the transistors 15, 16, and 19 and adding inverters 19A and 19B. In the level shift circuit LS1′ shown in FIG. 5, the current capacities of the transistors 17 and 18 are kept low. This increases the slew rate with which the drain voltages of the transistors 13 and 14 switch from high level to low level and decreases the slew rate with which the drain voltages of the transistors 13 and 14 switch from low level to high level. Thus, the outputs of the inverters 19A and 19B delay only when they turn from high level to low level.

The embodiments disclosed herein should be considered to be in every aspect illustrative and not restrictive, and the technical scope of the disclosure herein is defined not by the description of embodiments given above but by the scope of the appended claims and should be understood to encompass any modifications within a sense and scope equivalent to the claims.

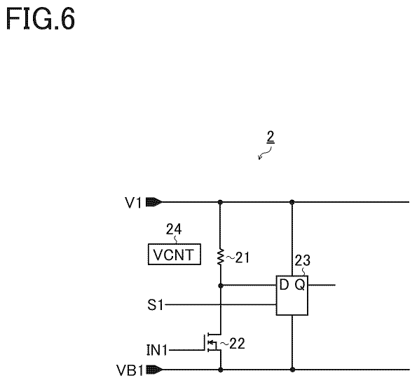

For example, the latch circuit is not limited to a differential latch circuit. Thus, for example, like the level shift circuit 2 shown in FIG. 6, it may be configured such that the latch control signal S1 and the input signal IN are fed to it completely independently of each other. The level shift circuit 2 includes a resistor 21, a transistor 22, a level latch circuit 23, and a voltage controller 24. Instead of the resistor 21, a constant current source may be used. A series circuit of the resistor 21 and the transistor 22 serves as the level information output circuit. The voltage controller 24 controls the first voltage V1 and the reference voltage VB1. The first voltage V1 and the reference voltage VB1 change with time as in the embodiments described above.

According to one aspect of what is disclosed herein, a level shift circuit (1) includes a level information output circuit (NA1, NA2, Q1, and Q6) configured to output level information on an input signal; a latch circuit (Q2 to Q5) configured to operate between a first voltage and a reference voltage lower than the first voltage to latch an output of the level information output circuit; and a voltage controller (CNT1) configured to raise the first voltage to a first set value after completion of latching by the latch circuit, then, when the first voltage reaches the first set value, to raise the reference voltage to a second set value, and then, after raising the reference voltage to the second set value, to raise the first voltage to a third set value. (A first configuration.)

The level shift circuit according to the first configuration described above can reduce the withstand voltage of its internal elements.

In the level shift circuit according to the first configuration described above, preferably, the voltage controller is configured to raise the reference voltage from the second setting value during a period in which the first voltage is raised from the first setting value to the third setting value. (A second configuration.)

The level shift circuit according to the second configuration described above can increase the first voltage to the third set value while keeping the difference between the first voltage and the reference voltage even lower. Thus, the level shift circuit according to the second configuration described above can reduce the withstand voltage of its internal elements even further.

In the level shift circuit according to the first or second configuration described above, preferably, an output stage of the level information output circuit is an NMOSFET configured to have its source fed with the reference voltage. (A third configuration.)

The level shift circuit according to the third configuration described above can easily reduce the withstand voltage of the output stage of the level information output circuit.

In the level shift circuit according to the third configuration described above, preferably, the latch circuit is a differential latch circuit. (A fourth configuration.)

The level shift circuit according to the fourth configuration described above can use the differential input circuit of the latch circuit as the input circuit for the input signal and the latch control signal.

In the level shift circuit according to the fourth configuration described above, preferably, the NMOSFET is configured to have its gate fed with a signal corresponding to both the input signal and a latch control signal that controls latching by the latch circuit. (A fifth configuration.)

The level shift circuit according to the fifth configuration described above can, with a simple circuit configuration, use the differential input circuit of the latch circuit as the input circuit for the input signal and the latch control signal.

In the level shift circuit according to the fourth or fifth configuration described above, preferably, after completion of latching by the latch circuit, the output of the level information output circuit is open. (A sixth configuration.)

The level shift circuit according to the sixth configuration described above can prevent, after completion of latching, the latch circuit from being reset.

What is claimed is:

1. A level shift circuit comprising:
a level information output circuit configured to output level information on an input signal,
a latch circuit configured to operate between a first voltage and a reference voltage lower than the first voltage to latch an output of the level information output circuit; and
a voltage controller configured to raise the first voltage to a first set value after completion of latching by the latch circuit, then, when the first voltage reaches the first set value, to raise the reference voltage to a second set value, and then, after raising the reference voltage to the second set value, to raise the first voltage to a third set value.

2. The level shift circuit according to claim 1,
wherein
the voltage controller is configured to raise the reference voltage from the second setting value during a period in which the first voltage is raised from the first setting value to the third setting value.

3. The level shift circuit according to claim 1,
wherein
an output stage of the level information output circuit is an NMOSFET configured to have a source thereof fed with the reference voltage.

4. The level shift circuit according to claim 2,
wherein
an output stage of the level information output circuit is an NMOSFET configured to have a source thereof fed with the reference voltage.

5. The level shift circuit according to claim 3,
wherein
the latch circuit is a differential latch circuit.

6. The level shift circuit according to claim 4,
wherein
the latch circuit is a differential latch circuit.

7. The level shift circuit according to claim 5,
wherein
the NMOSFET is configured to have a gate thereof fed with a signal corresponding to both the input signal and a latch control signal that controls latching by the latch circuit.

8. The level shift circuit according to claim 6,
wherein
the NMOSFET is configured to have a gate thereof fed with a signal corresponding to both the input signal and a latch control signal that controls latching by the latch circuit.

9. The level shift circuit according to claim 5,
wherein
after completion of latching by the latch circuit, the output of the level information output circuit is open.

10. The level shift circuit according to claim 6,
wherein
after completion of latching by the latch circuit, the output of the level information output circuit is open.

11. The level shift circuit according to claim 7,
wherein
after completion of latching by the latch circuit, the output of the level information output circuit is open.

12. The level shift circuit according to claim 8,
wherein
after completion of latching by the latch circuit, the output of the level information output circuit is open.
